(19) United States
(12) Patent Application Publication
(10) Pub. No.: US 2014/0070197 A1
(43) Pub. Date: Mar. 13, 2014

(54) METHOD FOR FORMING PATTERNED ORGANIC ELECTRODE

(71) Applicants: UNIVERSITY OF YAMANASHI, Kofu-shi (JP); TOKYO ELECTRON LIMITED, Minato-ku (JP)

(72) Inventors: Hiroshi SATO, Tsukuba-city (JP); Hidenori OKUZAKI, Kofu-shi (JP)

(73) Assignees: UNIVERSITY OF YAMANASHI, Kofu-shi (JP); TOKYO ELECTRON LIMITED, Minato-ku (JP)

(21) Appl. No.: 14/026,796

(22) Filed: Sep. 13, 2013

(30) Foreign Application Priority Data
Sep. 13, 2012 (JP) 2012-201989

(51) Int. Cl. H01L 51/00; H01L 51/10

(52) U.S. Cl. CPC H01L 51/0023; H01L 51/0022; H01L 51/105
USPC 257/40; 438/669; 257/744

(57) ABSTRACT

A method for forming a patterned organic electrode includes printing a toner on a surface of a substrate using a laser printer such that a reverse pattern formed of the toner is formed on the substrate, supplying a solution containing PEDOT and PSS onto the substrate having the reverse pattern formed of the toner such that the solution containing PEDOT and PSS is supplied into a region of the surface of the substrate not covered with the reverse pattern, drying the solution containing PEDOT and PSS supplied onto the substrate, and supplying onto the substrate a stripping solution containing a toner removing solvent which removes the toner and a high conductive solvent which selectively removes the PSS such that the reverse pattern formed of the toner is stripped from the substrate.

### CROSS-REFERENCE TO RELATED APPLICATIONS

The present application is based upon and claims the benefit of priority to Japanese Patent Application No. 2012-201989, filed Sep. 13, 2012, the entire contents of which are incorporated herein by reference.

### BACKGROUND OF THE INVENTION

1. Field of the Invention

An embodiment of the present invention relates to a method for forming a patterned organic electrode.

2. Description of Background Art

Organic transistors have been drawing attention because of their flexible, lightweight and thin characteristics, manufacturability on a large scale and cost performance. Generally in an organic transistor, a semiconductor layer and an insulator layer are formed by applying a soluble organic material, for example, by printing the organic material. Electrodes such as a gate, a source and a drain are formed by a vapor deposition of a metal such as Au. A material having mobility close to that of amorphous silicon, for example, pentacene, has been known as an organic material used for the semiconductor layer.

In recent years, techniques have been studied for forming an electrode in an organic transistor by using an organic material. One such technique is described, for example, in National Publication of International Patent Application No. 2004-530292. In the technique described in National Publication of International Patent Application No. 2004-530292, an organic electrode is patterned by dropping droplets of PEDOT (poly(3,4-ethylenedioxythiophene)) onto a substrate, or by ink-jet printing a PEDOT solution. The entire contents of this publication are incorporated herein by reference.

### SUMMARY OF THE INVENTION

According to one aspect of the present invention, a method for forming a patterned organic electrode includes printing a toner on a surface of a substrate using a laser printer such that a reverse pattern formed of the toner is formed on the substrate, supplying a solution containing PEDOT and PSS onto the substrate having the reverse pattern formed of the toner such that the solution containing PEDOT and PSS is supplied into a region of the surface of the substrate not covered with the reverse pattern, drying the solution containing PEDOT and PSS supplied onto the substrate, and supplying onto the substrate a stripping solution containing a toner removing solvent which removes the toner and a high conductive solvent which selectively removes the PSS such that the reverse pattern formed of the toner is stripped from the substrate.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a flowchart showing a method for forming a patterned organic electrode according to one embodiment;

FIGS. 2A, 2B and 2C show products prepared in steps of the method shown in FIG. 1;

FIG. 3 is a plan view showing one example of a pattern of a toner;

FIG. 4 is a sectional view showing an example of an organic transistor which can include an organic electrode formed by a method for forming a patterned organic electrode according to one embodiment;

FIG. 5 is a sectional view showing an example of an organic transistor which can include an organic electrode formed by a method for forming a patterned organic electrode according to one embodiment;

FIG. 6 is a sectional view showing an example of an organic transistor which can include an organic electrode formed by a method for forming a patterned organic electrode according to one embodiment;

FIG. 7 is a sectional view showing an example of an organic transistor which can include an organic electrode formed by a method for forming a patterned organic electrode according to one embodiment;

FIG. 8 is a graph showing a ratio of an integral value of an output intensity of XPS due to PEDOT to an integral value of output intensity of XPS due to PSS in Example 1, Comparative Example 1 and Comparative Example 2;

FIG. 9 is a graph showing measured values of electric conductivities of organic electrodes of Examples 2 to 8 and Comparative Examples 3 to 9; and

FIG. 10 is a graph showing measured values of thicknesses of organic electrodes of Examples 2 to 8 and Comparative Examples 3 to 9.

### DETAILED DESCRIPTION OF THE EMBODIMENTS

The embodiments will now be described with reference to the accompanying drawings, wherein like reference numerals designate corresponding or identical elements throughout the various drawings.

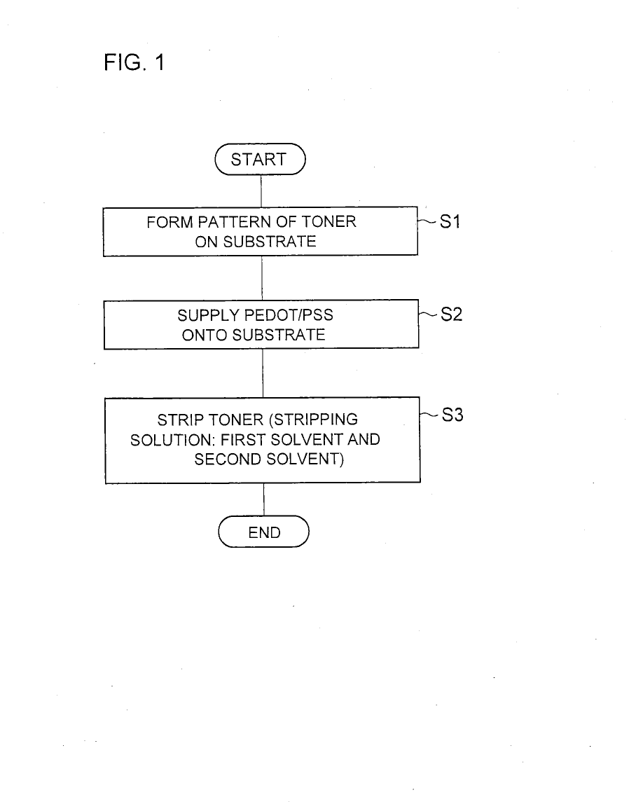

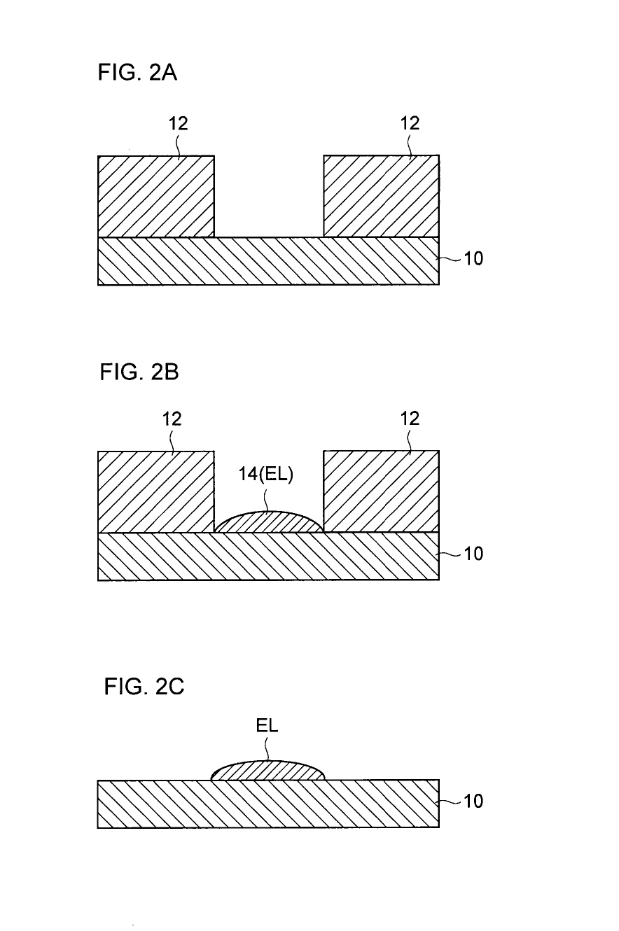

FIG. 1 is a flowchart showing a method for forming a patterned organic electrode according to one embodiment. FIG. 2 shows products prepared in steps of the method shown in FIG. 1. As shown in FIG. 1, in the method according to one embodiment, a pattern of a toner is printed on a substrate 10 by a laser printer in a step S1.

In the step S1, as shown in FIG. 2A, a pattern of a toner 12 is formed on the substrate 10. The substrate 10 provides a base for forming an organic electrode on the substrate 10. The substrate 10 may be an insulating base substrate. Alternatively, the substrate 10 may include an organic semiconductor layer or an organic insulator layer formed on the base substrate.

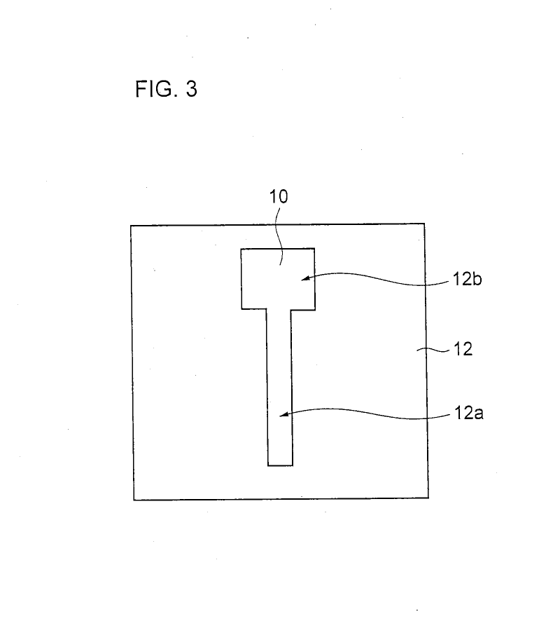

The pattern of the toner 12 formed in the step S1 is a reverse pattern of the pattern of the prepared organic electrode. FIG. 3 is a plan view showing one example of the pattern formed in the step S1 of the method shown in FIG. 1. One example of the pattern of the toner 12 shown in FIG. 3 includes an opening (12a) for preparing a body part of the organic electrode, and an opening (12b) for preparing a pad part of the organic electrode. The toner formed on the substrate 10 in the step S1 is not limited specifically, and the toner may contain iron oxide, a styrene-acrylic ester copolymer, and amorphous silica or the like, for example. The toner may contain carbon black instead of iron oxide.

Next, in the present method, a solution 14 containing PEDOT (poly(3,4-ethylenedioxythiophene)) and PSS (polystyrenesulfonate) is supplied onto the substrate 10 in a step S2. In the solution 14, PEDOT is contained as a conductive polymer material, and PSS is contained as an insulating dopant. The method for supplying the solution 14 is not limited specifically, and may employ methods such as ink-jet printing the solution containing the PEDOT and the PSS, or spin coating the solution.

In the step S2, the solution 14 is supplied onto the substrate 10 by utilizing a difference in water repellency between the toner 12 and the surface of the substrate 10. The toner 12 has water repellency higher than that of the surface of the substrate 10. That is, the substrate 10 has hydrophilicity higher than that of the toner 12. Therefore, in the step S2, the solution 14 containing PEDOT and PSS is supplied onto a region that is a partial region of the surface of the substrate 10 and is not covered with the toner 12.

In one embodiment, in order to increase the difference in water repellency between the toner 12 and the substrate 10, the surface of the substrate 10 may be ozonized before the step S1 or between the step S1 and the step S2. Ozone can be generated by irradiating an oxygen gas with ultraviolet rays.

In the method shown in FIG. 1, the solution 14 is dried, and the toner 12 is then stripped in a step (S3). An organic electrode (EL) patterned as shown in FIG. 2C is formed in the step (S3).

A stripping solution used in the step (S3) contains a first solvent for removing the toner, and a second solvent for selectively removing PSS. In the step (S3), the toner 12 can be removed by ultrasonic cleansing using the stripping solution. The method for removing the toner 12 is not limited to the ultrasonic cleansing as long as the stripping solution is used. In the step S3, when the toner 12 is stripped, the organic electrode (EL) is also exposed to the stripping solution. When the organic electrode (EL) is exposed to the stripping solution containing the second solvent, the PSS bonded to PEDOT is partially removed by the second solvent in the stripping solution. Therefore, even when the organic electrode (EL) is exposed to the stripping solution, the insulating PSS is selectively removed. As a result, degradation of the electric conductivity of the organic electrode (EL) is suppressed, and the electric conductivity is improved. By employing the step (S3), the removal of the toner 12 and the high electric conductivity of the organic electrode (EL) are both achieved in a single step.

Herein, examples of the above-mentioned first solvent include toluene and acetone. Examples of the second solvent include ethylene glycol (EG), dimethyl sulfoxide (DMSO), dimethylformamide (DMF), N-methyl-2-pyrrolidone (NMP), water, ethanol, isopropanol, and acetonitrile. The second solvent may be a solvent which can be uniformly mixed in the first solvent. Alternatively, the second solvent may be a solvent that cannot be uniformly mixed in the first solvent, i.e., a solvent contained in the stripping solution in a state where the second solvent is separated from the first solvent.

In one embodiment, the stripping solution may contain toluene as the first solvent, and ethylene glycol as the second solvent. Because ethylene glycol can accelerate the crystallization of PEDOT/PSS in a cross-linking reaction, ethylene glycol is thought to accelerate the high electric conductivity of the organic electrode (EL). In one embodiment, the stripping solution may contain 10% by mass or more and 40% by mass or less of ethylene glycol. When ethylene glycol is contained in the stripping solution at such a mass concentration, higher electric conductively is achieved in the organic electrode (EL) than that prior to the organic electrode being exposed to the stripping solution.

In one embodiment, the stripping solution may contain 10% by mass or more and 30% by mass or less of ethylene glycol. When the mass concentration of the ethylene glycol in the stripping solution is approximately 20% by mass, the electric conductivity of the organic electrode (EL) peaks in a relationship between the mass concentration of ethylene glycol in the stripping solution and the electric conductivity. Therefore, the electric conductivity of the organic electrode (EL) is brought close to a peak value by adjusting the mass concentration of ethylene glycol in the stripping solution in the range of 10% by mass or more and 30% by mass or less.

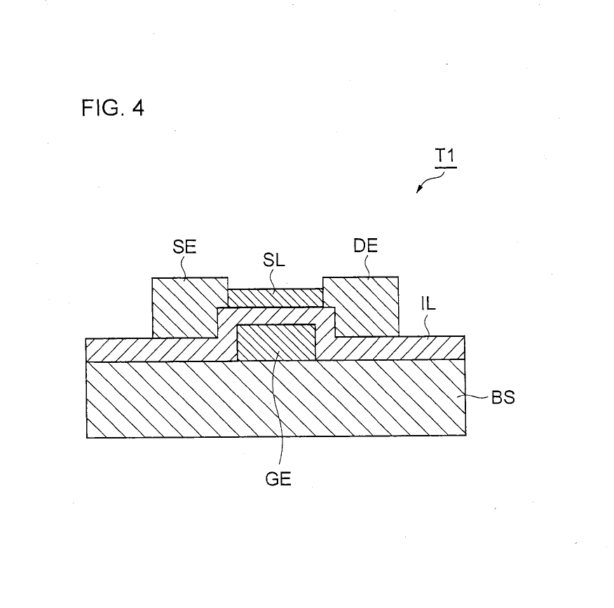

Hereinafter, the organic transistor that can include the organic electrode formed by the method of the above-mentioned embodiment will be described. FIGS. 4 to 7 are sectional views showing the organic transistors that can include the organic electrode formed by the method of the above-mentioned embodiment. The organic transistors shown in FIGS. 4 to 7 are field-effect transistors. The organic transistors are a bottom gate-bottom contact type, bottom gate-top contact type, top gate-bottom contact type, and top gate-top contact type organic transistors. The organic transistors (T1) to (T4) shown in FIGS. 4 to 7 each include a base substrate (BS), a gate electrode (GE), a source electrode (SE), a drain electrode (DE), an insulator layer (IL), and a semiconductor layer (SL).

In the bottom gate-bottom contact type organic transistor (T1) shown in FIG. 4, the gate electrode (GE) is formed on a main surface of the base substrate (BS). The insulator layer (IL) is formed so as to cover the gate electrode (GE) and the main surface of the base substrate (BS). The semiconductor layer (SL) is formed on the insulator layer (IL) above the gate electrode. The source electrode (SE) and the drain electrode (DE) are formed on the insulator layer (IL) such that an interface between the semiconductor layer (SL) on the gate electrode (GE) and the insulator layer (IL) is interposed between the source electrode (SE) and the drain electrode (DE).

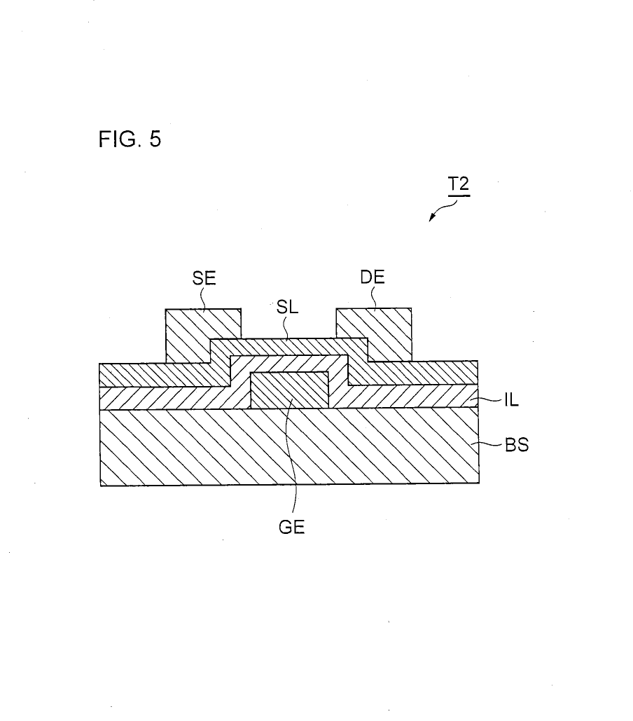

In the bottom gate-top contact type organic transistor (T2) shown in FIG. 5, the gate electrode (GE) is formed on the main surface of the base substrate (BS). The insulator layer (IL) is formed so as to cover the gate electrode (GE) and the main surface of the base substrate (BS). The semiconductor layer (SL) is uniformly on the insulator layer (IL). The source electrode (SE) and the drain electrode (DE) are formed on the insulator layer (IL) such that the interface between the semiconductor layer (SL) on the gate electrode (GE) and the insulator layer (IL) is interposed between the source electrode (SE) and the drain electrode (DE).

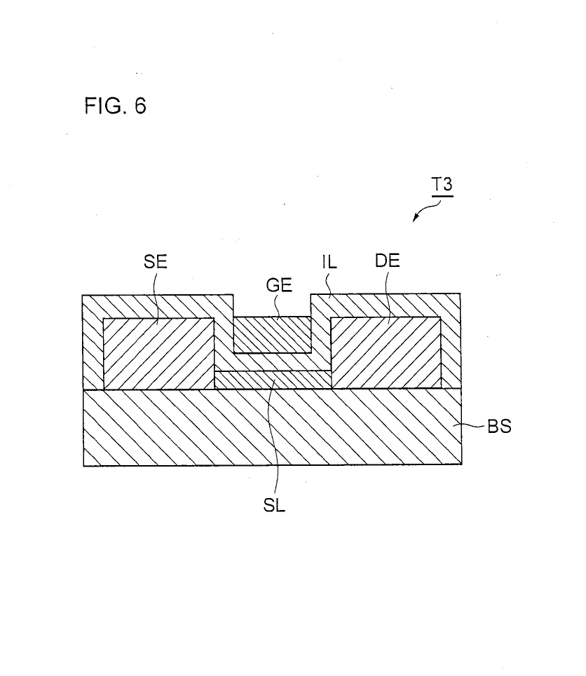

In the top gate-bottom contact type organic transistor (T3) shown in FIG. 6, the semiconductor layer (SL) is formed on the main surface of the base substrate (BS). The source electrode (SE) and the drain electrode (DE) are formed on the base substrate (BS) such that the semiconductor layer (SL) is interposed between the source electrode (SE) and the drain electrode (DE). The insulator layer (IL) is formed so as to cover the source electrode (SE), the drain electrode (DE) and the semiconductor layer (SL). The gate electrode (GE) is formed on the insulator layer (IL) above an interface, which is between the insulator layer (IL) and the semiconductor layer (SL) and which is interposed between the source electrode (SE) and the drain electrode (DE).

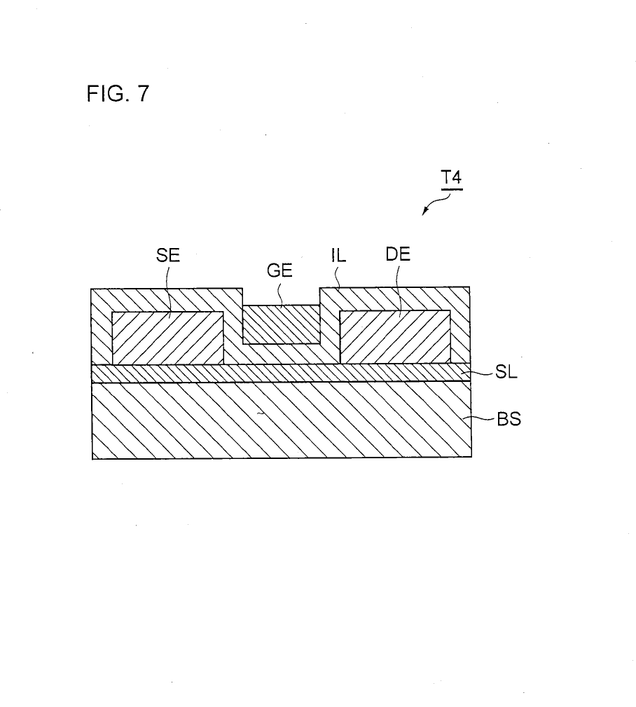

In the top gate-top contact type organic transistor (T4) shown in FIG. 7, the semiconductor layer (SL) is formed so as to cover the main surface of the base substrate (BS). The source electrode (SE) and the drain electrode (DE) are formed on the semiconductor layer (SL) so as to be separated from each other. The insulator layer (IL) is formed so as to cover the source electrode (SE), the drain electrode (DE) and the semiconductor layer (SL). The gate electrode (GE) is formed on the insulator layer (IL) above the interface between the insulator layer (IL) and the semiconductor layer (SL) between the source electrode (SE) and the drain electrode (DE).

In the organic transistors shown in FIGS. 4 to 7, the base substrate (BS) is an insulating substrate. The base substrate (BS) may be made of, for example, glass, quartz, monocrystalline silicon, polycrystalline silicon, amorphous silicon, or a synthetic resin or the like. Examples of the synthetic resin include polyethylene terephthalate (PET), polyethylene naphthalate, polyether sulphone, polyether imide, polyether ether ketone, polyphenylene sulphide, polyarylate, polyimide, polycarbonate, a cyclic polyolefin or the like.

In the organic transistors shown in FIGS. 4 to 7, the semiconductor layer (SL) is an organic semiconductor layer. Examples of an organic semiconductor material for forming the organic semiconductor layer include materials having desired semiconducting properties such as an aromatic compound, a chain compound, an organic pigment, and an organic silicon compound. More specific examples of the organic semiconductor material include low-molecular organic compounds such as pentacene, and polymer organic compounds such as polypyrroles, polythiophenes, polyisothianaphthenes, poly(thienylene vinylenes), poly(p-phenylenevinylenes), polyanilines, polyacetylenes, and poly(azulenes).

An inorganic insulating material or an organic insulating material generally used for the organic transistor can be used for insulator layer (IL) in the organic transistors shown in FIGS. 4 to 7. In addition to glass, silicon oxide (SiO₂), silicon nitride and aluminum nitride, examples of the inorganic insulating material include metal oxides such as aluminum oxide, tantalum oxide, titanium oxide, tin oxide, vanadium oxide, strontium titanate, barium strontium titanate, barium zirconate titanate, lead zirconate titanate, lead lanthanum titanate, barium titanate, barium magnesium fluoride, bismuth titanate, bismuth strontium titanate, bismuth strontium tantalate, bismuth niobium tantalate, yttrium trioxide, and hafnium oxide.

Examples of the organic insulating material include polymer materials such as polyimide, polyamide, polyester, polyacrylate, a phenol-based resin, a fluorine-based resin, an epoxy-based resin, a novolac-based resin, and a vinyl-based resin.

The organic electrode (EL) formed by the method of the above-mentioned embodiment can be used for all or part of the gate electrode (GE), source electrode (SE), and drain electrode (DE) of each of the organic transistors shown in FIGS. 4 to 7. The other part of the gate electrode (GE), source electrode (SE), and drain electrode (DE) of each of the organic transistors shown in FIGS. 4 to 7 may be made of a metal material such as Ag, Au, Ta, Ti, Al, Zr, Cr, Nb, Hf, Mo, an alloy thereof, an indium tin oxide alloy (ITO), or indium zinc oxide (IZO); a silicon-based material such as silicon single crystal, polycrystal silicon, or amorphous silicon; and a conductive material such as a carbon material, for example, carbon black or graphite.

Each part of the organic transistors of FIGS. 4 to 7 may be prepared as described later. When the insulator layer (IL) is made of the inorganic insulating material, the insulator layer (IL) may be formed by a dry process or a wet process. When the insulator layer (IL) is made of the organic insulating material, the insulator layer (IL) may be formed by the wet process. For example, a vacuum evaporation method, a molecular beam epitaxial deposition method, an ion cluster beam method, a low energy ion beam method, an ion plating method, a CVD method, a sputtering method, and an atmospheric pressure plasma method or the like can be used as the dry process. For example, a coating method such as a spin coating method, a die coating method, a roll coating method, a bar coating method, an LB method, a dip coating method, a spray coating method, a blade coating method, or a cast method, an ink-jet method, a screen printing method, a pad printing method, a flexo printing method, a micro contact printing method, a gravure printing method, an offset printing method, and a gravure-offset printing method or the like can be used as the wet process.

The semiconductor layer (SL) may be formed by a dry process or a wet process. For example, a vacuum evaporation method, a molecular beam epitaxial deposition method, an ion cluster beam method, a low energy ion beam method, an ion plating method, a CVD method, a sputtering method, and an atmospheric pressure plasma method or the like can be used as the dry process. For example, a coating method such as a spin coating method, a die coating method, a roll coating method, a bar coating method, an LB method, a dip coating method, a spray coating method, a blade coating method, or a cast method, an ink-jet method, a screen printing method, a pad printing method, a flexo printing method, a micro contact printing method, a gravure printing method, an offset printing method, and a gravure-offset printing method or the like can be used as the wet process.

A part or all of the gate electrode (GE), source electrode (SE), and drain electrode (DE) may be formed by the method for forming the patterned organic electrode of the above-mentioned embodiment. After a conductive material is uniformly formed on a base, the other part of the gate electrode (GE), source electrode (SE), and drain electrode (DE) may be formed by patterning the conductive material according to a photolithographic technique, or may be formed by patterning the conductive material according to a screen printing method, an ink-jet method, and a vapor-deposition method or the like.

### EXAMPLES

Hereinafter, the present invention will be described in more detail with reference to examples, but the present invention is not limited to these examples.

### Example 1 and Comparative Example 1

In accordance with a method shown in FIG. 1, a toner pattern was formed on a substrate made of polyethylene terephthalate. A solution containing PEDOT and PSS was dropped onto the substrate and dried. The toner was then stripped by a stripping solution containing 20% by mass of polyethylene glycol and 80% by mass of toluene to prepare an organic electrode. The organic electrode was used as Example 1. In Example 1, a laser printer LBP B10 manufactured by Canon Inc. was used to form the toner pattern. The organic electrode of Example 1 before the toner was stripped was used as Comparative Example 1. An organic electrode manufactured under a preparation condition different from that of Example 1, in that the stripping solution containing only toluene was used, was used as Comparative Example 2.

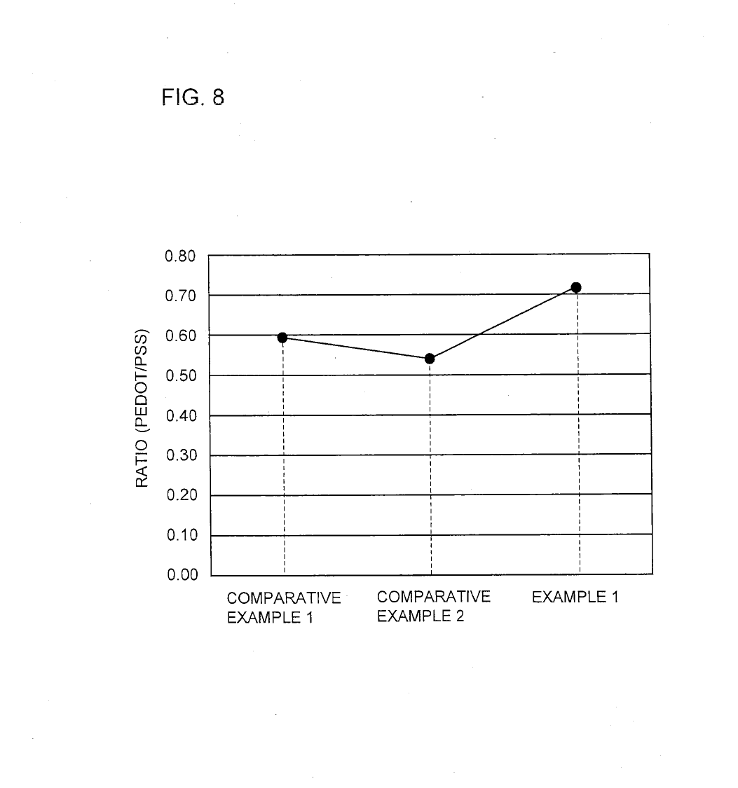

The compositions of the organic electrodes of Example 1, Comparative Example 1 and Comparative Example 2 were analyzed by XPS (X-ray photoelectron spectroscopy). Specifically, attention was paid to a 2 p orbit of sulfur to obtain output data of XPS. Intensity (arbitrary unit) included in the obtained output data was divided into intensity due to PEDOT and intensity due to PSS by waveform separation to obtain a ratio of an integral value of the intensity due to the PEDOT to an integral value of the intensity due to the PSS. The result is shown in FIG. 8.

As shown in FIG. 8, the ratio of the amount of PEDOT to the amount of PSS in the organic electrode of Comparative Example 2 prepared using the stripping solution containing only toluene decreased as compared with that of the organic electrode in a state before the toner was stripped, i.e., Comparative Example 1. On the other hand, the ratio of the amount of PEDOT to the amount of PSS in the organic electrode of Example 1 increased as compared with that of the organic electrode in a state before the toner was stripped, i.e., Comparative Example 1. From this, it was confirmed that the amount of PSS relative to the amount of PEDOT in the organic electrode of Example 1 decreased due to the exposure to the stripping solution. Therefore, it was confirmed that degradation in the electric conductivity of the organic electrode is suppressed and the electric conductivity is improved by adding ethylene glycol to a stripping solution of the toner so as to selectively remove PSS from the organic electrode.

### Examples 2 to 7 and Comparative Examples 3 to 10

A toner pattern was formed on a substrate made of polyethylene terephthalate by the method shown in FIG. 1. A solution containing PEDOT and PSS was dropped onto the substrate and dried. The toner was then stripped by a stripping solution containing polyethylene glycol and toluene to prepare organic electrodes. The organic electrodes were used as Examples 2 to 7. In Examples 2 to 7, the amount of ethylene glycol contained in the stripping solution was changed by 10% by mass, ranging from 10% by mass to 60% by mass respectively. As for Comparative Example 3, an organic electrode was prepared under the same conditions as those of Examples 2 to 7 except that the stripping solution containing only toluene was used. The organic electrodes of Comparative Example 3 and Examples 2 to 7 before the toner was stripped were respectively used as Comparative Examples 4 to 10. In Examples 2 to 7 and Comparative Examples 3 to 10, a laser printer LBP B 10 manufactured by Canon Inc. was used to form the toner pattern.

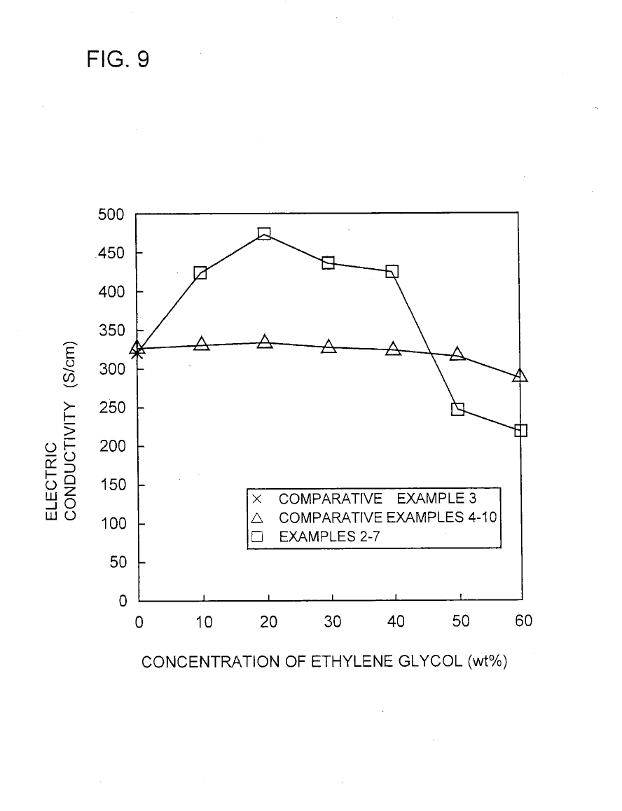

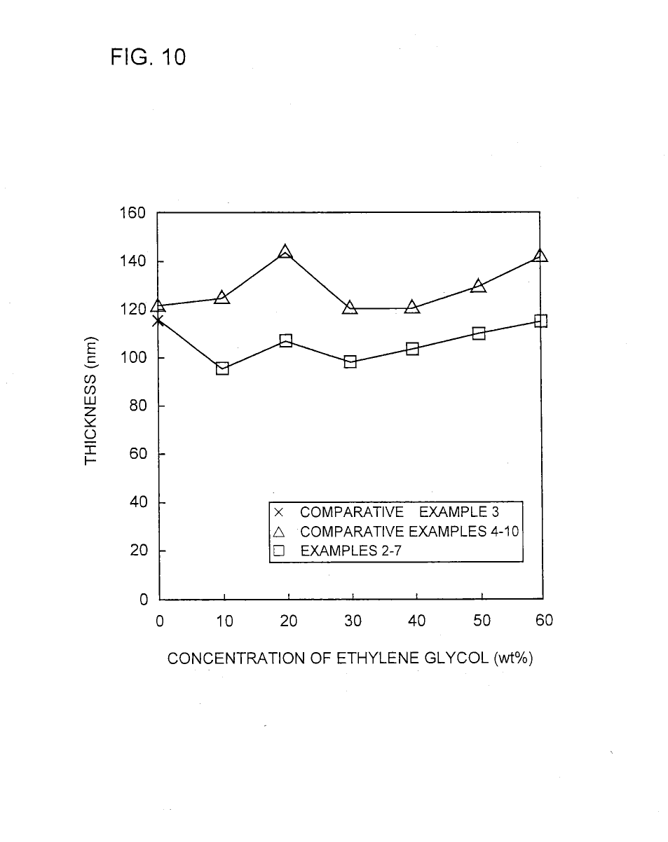

The electric conductivities of the organic electrodes of Examples 2 to 7 and Comparative Examples 4 to 10 were measured. The thicknesses of the organic electrodes of Examples 2 to 7 and Comparative Examples 4 to 10 were measured. The measurement results of the electric conductivities are shown in FIG. 9. The measurement results of the thicknesses of the organic electrodes are shown in FIG. 10.

As shown in FIG. 9, when the mass concentration of ethylene glycol contained in the stripping solution was 10% by mass or more and 40% by mass or less, it was confirmed that the electric conductivity of the organic electrode was mass considerably higher than that of the organic electrode before the toner was stripped. When the mass concentration of ethylene glycol contained in the stripping solution was 20% by mass, it was confirmed that the electric conductivity of the organic electrode was about 1.5 times that of the organic electrode before the toner was stripped, and reached a peak value. It was confirmed that the electric conductivity of the organic electrode can be brought close to the peak value by adjusting the mass concentration of ethylene glycol to be in a range of 10% by mass and 30% by mass.

As shown in FIG. 10, the thickness of the organic electrode of examples in which the toner was stripped by the stripping solution containing toluene and ethylene glycol was smaller than that of the organic electrode of the state before the toner was stripped, i.e., comparative examples. From those results, it is thought that when the toner is stripped by the stripping solution containing toluene and ethylene glycol, the organic electrode is exposed to the stripping solution so as to cause PSS to be selectively removed.

Because the viscosity and pH adjustment or the like of a material discharged from a nozzle are required in ink-jet printing, the characteristics of an organic material cannot sufficiently be utilized. Although it is an option to pattern the organic material using a lithography technology, the electric conductivity of the electrode may be degraded because the organic material for an electrode is exposed to a resist removing solution.

A method for forming organic electrodes while suppressing degradation of electric conductivity of the patterned organic electrode and improving the electric conductivity has been requested.

Using the method for forming the patterned organic electrode according to one embodiment of the present invention, stripping the toner and obtaining high electric conductivity of the organic electrode are both achieved when a solvent capable of selectively removing PSS (referred to as a “high conductive solvent”) is added to the solvent for removing the toner.

In one aspect of the present invention, a method for forming a patterned organic electrode includes the following steps: (a) forming a pattern of a toner on a substrate by a laser printer; (b) supplying a solution containing PEDOT and PSS onto the substrate; and (c) stripping the toner by a stripping solution containing a first solvent for removing a toner and a second solvent for selectively removing PSS.

In the method of the present embodiment, the patterned organic electrode is formed by supplying the solution containing PEDOT and PSS onto the substrate on which the toner functioning as a mask is printed, and the toner is then stripped by the stripping solution. When the organic electrode is exposed to the stripping solution, the PSS bonded to PEDOT is partially removed by the second solvent in the stripping solution, i.e., the high conductive solvent. Herein, PEDOT is a conductive polymer material, and PSS (poly(4-styrenesulfonic acid)) is an insulating dopant. Therefore, according to the method, the organic electrode is exposed to the stripping solution, and the PSS as an insulating dopant is selectively removed by the high conductive solvent. As a result, degradation of the electric conductivity of the organic electrode is suppressed, and the electric conductivity is improved. The removal of the toner and the improvement in the electric conductivity of the organic electrode are both achieved in one step.

The stripping solution may contain toluene as the first solvent and ethylene glycol as the second solvent.

It is an option for the stripping solution to contain ethylene glycol at 10% by mass or more but 40% by mass or less. When the stripping solution contains ethylene glycol in such a mass concentration range, the organic electrode achieves an electric conductivity considerably higher than that of the organic electrode before being exposed to the stripping solution.

It is also an option for the stripping solution to contain ethylene glycol at 10% by mass or more but 30% by mass or less. When the mass concentration of the ethylene glycol in the stripping solution is about 20% by mass, the electric conductivity of the organic electrode reaches a peak in the relationship between the mass concentration of ethylene glycol in the stripping solution and the electric conductivity. Therefore, by adjusting the mass concentration of ethylene glycol in the stripping solution in the range of 10% by mass or more and 30% by mass or less, the electric conductivity of the organic electrode can be brought close to the peak.

As described above, one aspect and embodiment of the present invention provides a method for forming organic electrodes while suppressing degradation of the electric conductivity of the patterned organic electrode and improving the electric conductivity.

Obviously, numerous modifications and variations of the present invention are possible in light of the above teachings. It is therefore to be understood that within the scope of the appended claims, the invention may be practiced otherwise than as specifically described herein.

What is claimed is:

1. A method for forming a patterned organic electrode, comprising:
printing a toner on a surface of a substrate using a laser printer such that a reverse pattern comprising the toner is formed on the substrate;
supplying a solution comprising PEDOT and PSS onto the substrate having the reverse pattern comprising the toner such that the solution comprising PEDOT and PSS is supplied into a region of the surface of the substrate not covered with the reverse pattern;
drying the solution comprising PEDOT and PSS supplied onto the substrate; and
supplying onto the substrate a stripping solution comprising a toner removing solvent which removes the toner and a high conductive solvent which selectively removes the PSS such that the reverse pattern comprising the toner is stripped from the substrate.

2. The method for forming a patterned organic electrode according to claim 1, wherein the toner removing solvent in the stripping solution is toluene, and the high conductive solvent in the stripping solution is ethylene glycol.

3. The method for forming a patterned organic electrode according to claim 2, wherein the stripping solution includes ethylene glycol at 10% by mass or more and 40% by mass or less.

4. The method for forming a patterned organic electrode according to claim 3, wherein the stripping solution includes ethylene glycol at 30% by mass or less.

5. The method for forming a patterned organic electrode according to claim 1, wherein the supplying of the solution comprising PEDOT and PSS includes ink-jet printing the solution comprising PEDOT and PSS on the substrate.

6. The method for forming a patterned organic electrode according to claim 1, wherein the supplying of the solution comprising PEDOT and PSS includes spin coating the solution comprising PEDOT and PSS on the substrate.

7. The method for forming a patterned organic electrode according to claim 1, further comprising applying ozone treatment on the surface of the substrate.

8. The method for forming a patterned organic electrode according to claim 1, wherein the supplying of the stripping solution includes ultrasonic cleansing.

9. The method for forming a patterned organic electrode according to claim 1, wherein the toner removing solvent in the stripping solution includes at least one of toluene and acetone.

10. The method for forming a patterned organic electrode according to claim 1, wherein the high conductive solvent in the stripping solution includes at least one solvent selected from the group consisting of ethylene glycol, dimethyl sulfoxide, dimethylformamide, N-methyl-2-pyrrolidone, water, ethanol, isopropanol and acetonitrile.

11. The method for forming a patterned organic electrode according to claim 1, wherein the toner removing solvent in the stripping solution includes at least one of toluene and acetone, and the high conductive solvent in the stripping solution includes at least one solvent selected from the group consisting of ethylene glycol, dimethyl sulfoxide, dimethylformamide, N-methyl-2-pyrrolidone, water, ethanol, isopropanol, and acetonitrile.

12. An organic electrode produced by a process comprising the method for forming a patterned organic electrode according to claim 1.

13. An organic electrode produced by a process comprising the method for forming a patterned organic electrode according to claim 2.

14. An organic electrode produced by a process comprising the method for forming a patterned organic electrode according to claim 3.

15. An organic electrode produced by a process comprising the method for forming a patterned organic electrode according to claim 4.

16. An organic transistor, comprising:
the substrate; and
an organic electrode produced by a process comprising the method for forming a patterned organic electrode according to claim 1.

17. An organic transistor, comprising:
the substrate; and
an organic electrode produced by a process comprising the method for forming a patterned organic electrode according to claim 2.

18. An organic transistor, comprising:
the substrate; and
an organic electrode produced by a process comprising the method for forming a patterned organic electrode according to claim 3.

19. An organic transistor, comprising:
the substrate; and
an organic electrode produced by a process comprising the method for forming a patterned organic electrode according to claim 4.
